(19) United States
(12) Patent Application Publication
(10) Pub. No.: US 2010/0019780 A1
(43) Pub. Date: Jan. 28, 2010

(54) MULTI-AXIS CAPACITIVE SENSOR

(76) Inventor: Mihai Bulea, Santa Clara, CA (US)

Correspondence Address: SYNAPTICS C/O WAGNER BLECHER LLP, 123 WESTRIDGE DRIVE, WATSONVILLE, CA, 95076, US

(21) Appl. No.: 12/179,523

(22) Filed: Jul. 24, 2008

(51) Int. Cl. G01R 27/26

(52) U.S. Cl. 324/662

(57) ABSTRACT

Methods for determining the position of multiple objects concurrently disposed within a capacitive sensing region are described. In one embodiment, indicia are received from a first plurality of capacitive sensor electrodes oriented along a first axis. Indicia are received from a second plurality of capacitive sensor electrodes oriented along a second axis, wherein the second axis is oriented non-parallel to the first axis. Indicia are received from a third plurality of capacitive sensor electrodes oriented along a third axis, wherein the third axis is oriented non-parallel to the first axis and the second axis. Then, the indicia received from the first plurality of capacitive sensor electrodes, the indicia received from the second plurality of capacitive sensor electrodes, and the indicia received from the third plurality of capacitive sensor electrodes is used to determine the positions of the multiple objects concurrently disposed within the capacitive sensing region.

### BACKGROUND

Sensing devices, otherwise known as touch sensing devices or proximity sensors are widely used in modern electronic devices. A capacitive sensing device is often used for touch based navigation, selection, or other input, in response to a finger, stylus, or other object being placed on or in proximity to a sensor of the capacitive sensing device. In such a capacity, capacitive sensing devices are often employed in computers (e.g. notebook/laptop computers), media players, multi-media devices, remote controls, personal digital assistants, smart devices, telephones, and the like. Un-patterned sheet sensors (both capacitive and resistive) are often employed as a simple and economical method means for implementing attractive sensors for sensing contact, touch, and/or proximity based inputs.

However, there exist many limitations to the current state of technology with respect to capacitive sensing devices. For example, during operation input provided to a capacitive sensing device may become distorted due to the presence of noise. Furthermore, uncertainty may result when objects are too close to each other and such objects are used to input information into a capacitive sensing device. For example, two fingers interacting concurrently with the same capacitive sensing device may get so close to each other that they cannot be readily distinguished.

### SUMMARY

Methods for determining the position of multiple objects concurrently disposed within a capacitive sensing region are described. In one embodiment, indicia are received from a first plurality of capacitive sensor electrodes oriented along a first axis. Indicia are received from a second plurality of capacitive sensor electrodes oriented along a second axis, wherein the second axis is oriented non-parallel to the first axis. Indicia are received from a third plurality of capacitive sensor electrodes oriented along a third axis, wherein the third axis is oriented non-parallel to the first axis and the second axis. Then, the indicia received from the first plurality of capacitive sensor electrodes, the indicia received from the second plurality of capacitive sensor electrodes, and the indicia received from the third plurality of capacitive sensor electrodes is determined. The positions of the multiple objects are concurrently disposed within the capacitive sensing region.

### BRIEF DESCRIPTION OF THE DRAWINGS

The accompanying drawings, which are incorporated in and form a part of this specification, illustrate embodiments of the technology for gradient sensors and, together with the description, serve to explain principles discussed below:

FIG. 1 is a block diagram of an example capacitive sensing apparatus in accordance with embodiments of the present technology.

FIG. 2 is a layout of an example capacitive sensing apparatus with a first, second, and third plurality of capacitive sensor electrodes oriented along three non-parallel axes in accordance with embodiments of the present technology.

FIG. 3 is a diagram displaying objects concurrently disposed within capacitive sensing region and corresponding graphs adjacent thereby in accordance with embodiments of the present technology.

FIG. 4 is a diagram displaying objects concurrently disposed within capacitive sensing region and corresponding graphs in accordance with embodiments of the present technology.

FIG. 5 is a graph displaying an example best position estimation for objects concurrently disposed within a capacitive sensing region in accordance with embodiments of the present technology.

FIG. 6 is a block diagram of an example controller in accordance with embodiments of the present technology.

FIG. 7 is a flowchart of an example method for determining the position of multiple objects concurrently disposed within a capacitive sensing region in accordance with embodiments of the present technology.

The drawings referred to in this description should not be understood as being drawn to scale unless specifically noted.

### DETAILED DESCRIPTION

Reference will now be made in detail to embodiments of the presented technology, examples of which are illustrated in the accompanying drawings. While the presented technology will be described in conjunction with embodiments, it will be understood that the descriptions are not intended to limit the presented technology to these embodiments. On the contrary, the descriptions are intended to cover alternatives, modifications and equivalents, which may be included within the spirit and scope as defined by the appended claims. Furthermore, in the following detailed description, numerous specific details are set forth in order to provide a thorough understanding of the presented technology. However, it will be obvious to one of ordinary skill in the art that the presented technology may, in some embodiments, be practiced without these specific details. In other instances, well known methods, procedures, components, and circuits have not been described in detail as not to unnecessarily obscure aspects of the presented technology.

### Overview of Discussion

The capacitive sensing apparatuses described herein enable the positions of multiple objects concurrently disposed within a capacitive sensing region to be determined. For example, a number (n) objects (n) interacting with a capacitive sensing region may be sensed using multiple capacitive sensor electrodes oriented along more than two axes (n+1). The resulting indicia are then used to determine an object's best estimated position for what may otherwise be an ambiguously positioned object.

The discussion will begin by focusing on an example capacitive sensing apparatus comprising multiple sensor arrays in accordance with embodiments of the present technology. The discussion will then focus on embodiments of a system and method for enabling the determination of positions of multiple objects concurrently disposed within a capacitive sensing region.

### Capacitive Sensing Apparatus Comprising Multiple Sensor Arrays

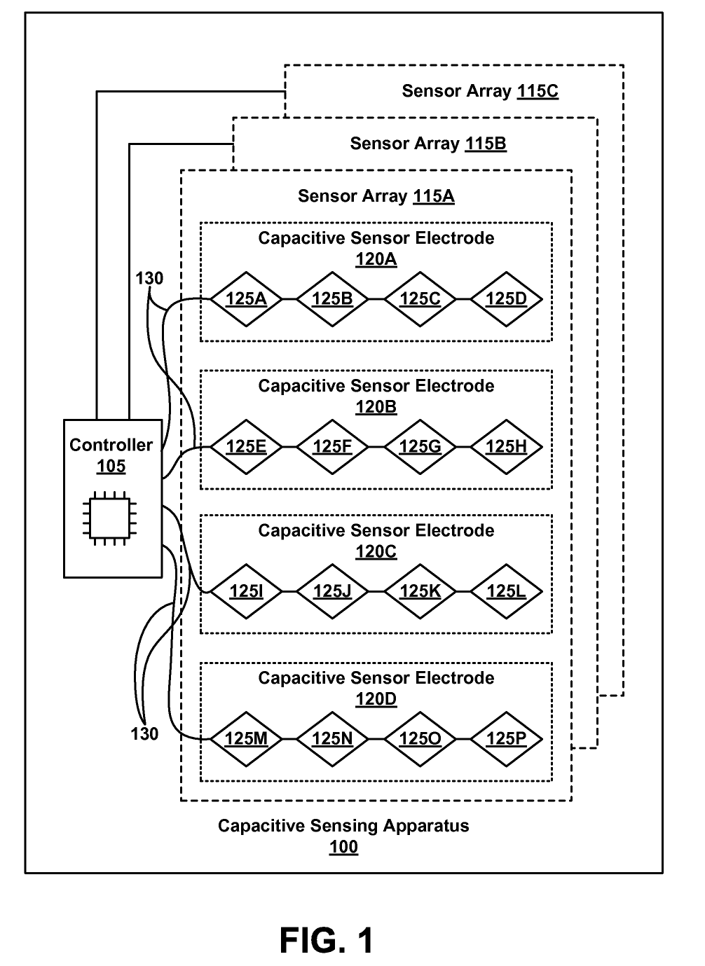

FIG. 1 is a block diagram of an example capacitive sensing apparatus 100 in accordance with embodiments of the present technology. Capacitive sensing apparatus 100 comprises a plurality of sensor arrays 115A, 115B, and 115C. Additionally, sensor arrays 115A, 115B, and 115C may be in different axis orientations relative to each other. In accordance with one embodiment, each sensor array 115A-115C is used for sensing a user's interaction with a capacitive sensing apparatus. Such user interaction may occur with proximity or contact based input performed with one or more user digits, a palm, and/or a stylus or other device used for interaction with the capacitive sensor device.

Sensor array 115A is comprised of a plurality of capacitive sensor electrodes 120A, 120B, 120C, and 120D. Further, each capacitive sensor electrode 120A-120D is comprised of a plurality of sensor elements 125A-125P. Embodiments in accordance with the present technology are well suited to capacitive sensor arrays having more than three sets of capacitive sensing electrodes. Similarly, embodiments in accordance with the present technology are well suited to use with capacitive sensor electrodes comprised of a fewer or greater number of sensor elements.

Referring still to FIG. 1, sensor elements 125A-125D are electrically coupled with each other and controller 105 via a plurality of traces 130. It should also be noted that embodiments in accordance with the present technology are also well suited to utilizing sensor elements of various shapes, sizes, and configurations.

### System and Method of Determining the Position of Multiple Objects Concurrently Disposed Within a Capacitive Sensing Region

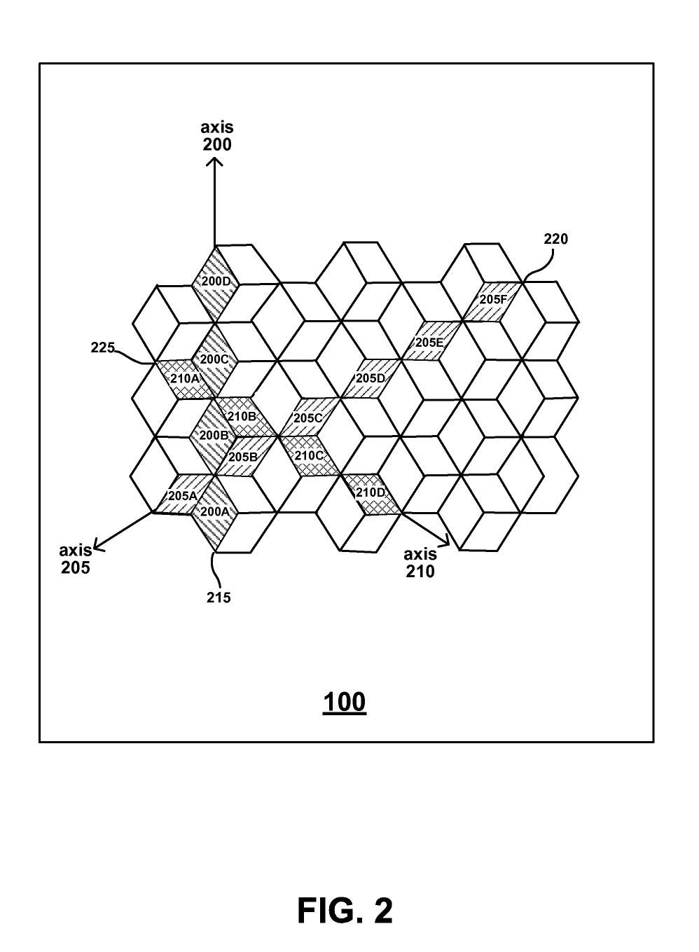

FIG. 2 is a schematic of an example capacitive sensing apparatus 100 with a first, second, and third plurality of capacitive sensor electrodes oriented along three non-parallel axes in accordance with embodiments of the present technology. One or more capacitive sensor electrodes are arranged around the same axis in the same or a different plane. For purposes of clarity and brevity, each of the three non-parallel axes 200, 205, and 210 comprising one or more capacitive sensor electrodes, is represented by a single capacitive sensor electrode 215, 220, and 225, respectively. Each capacitive sensor electrode 215, 220, and 225 is disposed substantially in parallel to the same axis. For example, a first capacitive sensor electrode typically shown as 215 is disposed substantially in parallel to a first axis 200. First capacitive sensor electrode 215 is comprised of sensor elements typically shown as 200A-200D.

Similarly, a second capacitive sensor electrode typically shown as 220 is disposed substantially in parallel to a second axis 205. Second capacitive sensor electrode 220 is comprised of sensor elements typically shown as 205A-205F. Additionally, a third capacitive sensor electrode typically shown as 225 is disposed substantially in parallel to a third axis 210. Third capacitive sensor electrode 225 is comprised of sensor elements typically shown as 210A-210D.

Embodiments in accordance with the present invention are well suited to use with various numbers of sets of capacitive sensing electrodes having various numbers of sensor elements disposed substantially in parallel to various numbers of axes.

In one embodiment, sensor elements 200A-200D comprising first capacitive sensor electrode 215 and sensor elements 205A-205F comprising second capacitive sensor electrode 220 are located on separate layers. Furthermore, in one such embodiment in which capacitive sensor electrodes 215 and 220 are arranged on separate layers, they are physically arranged with respect to each other such that in a projection of first sensor elements 200A-200D and second sensor elements 205A-205F onto a common plane, first sensor elements 200A-200D and second sensor elements 205A-205F are physically interdigitated in a space filling pattern. One such example of a physically interdigitated space filling pattern is shown in FIG. 2.

It should be noted however, that the present invention is well suited to having capacitive sensor electrodes 215, 220, and 225 located on the same layer or having a subset of capacitive sensor electrodes 215, 220, and 225 located on one layer and another subset of capacitive sensor electrodes 215, 220, and 225 located on a separate layer.

Furthermore, in one embodiment, axes 200, 205, and 210 are arranged with substantially the same angle of separation there between. However, the present invention is well suited to having axes 200, 205, and 210 positioned at varying angles of separation with respect to each other.

More generally, in embodiments in accordance with the present technology, in order to determine the position of n objects concurrently disposed within a capacitive sensing region, at least n+1 sets of capacitive sensing electrodes disposed substantially in parallel to n+1 axes are used. For example, assume that capacitive sensing apparatus 100 must be able to determine the position of two objects concurrently disposed within a capacitive sensing region. It should be noted that such a determination is particularly useful to distinguish gesturing operations such as, for example, pinching with two fingers performed by a user.

In such a case, the present technology would utilize at least three sets of capacitive sensing electrodes diposed in parallel to each axis of at least three non-parallel axes to determine the position of the two objects. Hence, embodiments in accordance with the present technology are well suited to determining the position of two or more objects concurrently disposed within a capacitive sensing region.

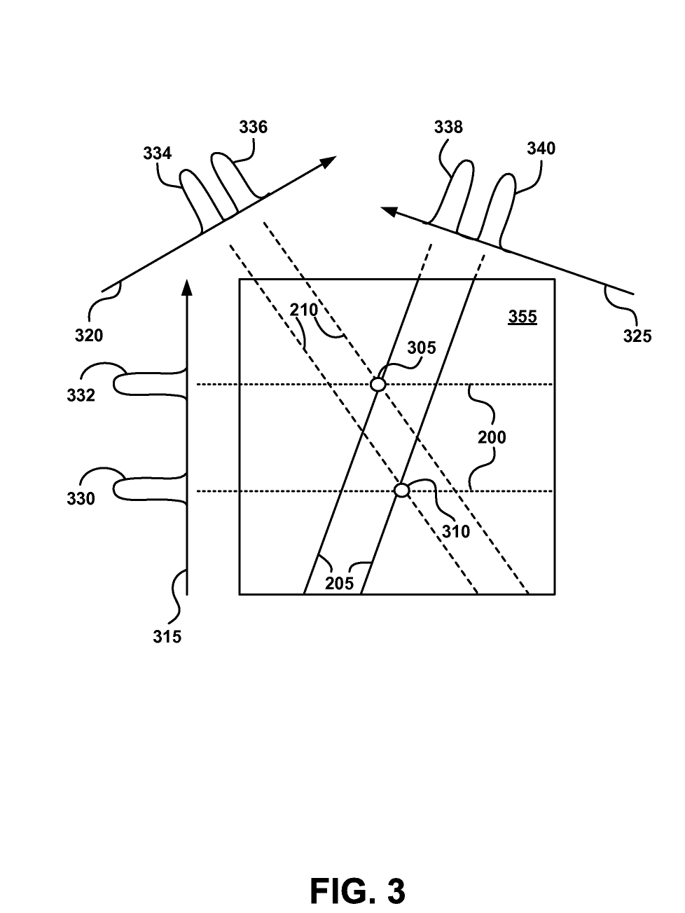

FIG. 3 is a diagram displaying objects concurrently disposed within capacitive sensing region 355 at locations 305 and 310 and corresponding graphs 315, 320, and 325 adjacent thereby according to one embodiment. As will be described in detail below, graphs 315, 320, and 325 provide a graphical representation of indicia received from capacitive sensor electrodes disposed substantially in parallel to axes 200, 205, and 210, respectively.

Consider the example wherein two objects are concurrently disposed within capacitive sensing region 355. For purposes of the following example, assume that the two objects are comprised of a thumb and a pointer finger of a user. As already noted, it is understood that the user's thumb and pointer finger may be used, for example, to perform a pinching operation. However, in other embodiments, the two objects concurrently disposed within capacitive sensing region 355 may be any digit on a hand or other objects.

In such an example, location 305 represents the location at which the pointer finger interacts with capacitive sensing region 355. Similarly, location 310 represents the location at which the thumb interacts with capacitive sensing region 355. As shown on FIG. 3, location 305 corresponds to the intersection of a set of capacitive sensor electrodes that are disposed substantially in parallel to axes 200, 205, and 210. Additionally, location 310 corresponds to the intersection of different sets of capacitive sensor electrodes that also are disposed substantially in parallel to axes 200, 205, and 210.

When the pointer finger is at location 305, indicia are generated by capacitive sensor electrodes that are disposed substantially in parallel to axis 200. This indicia is represented by peak 332 on graph 315. Furthermore, indicia are also generated by capacitive sensor electrodes that are disposed substantially in parallel to axes 205 and 210, and are represented by peaks on graphs 325 and 320 respectively. Similarly, when the thumb is at location 310, indicia are generated by capacitive sensor electrodes that are disposed substantially in parallel to axes 200, 205, and 210, and are represented by the peaks on graphs 315, 325, and 320 respectively.

The indicia generated by the capacitive sensor electrodes are relayed to controller 105. As will be described in detail below, controller 105 is configured to utilize indicia to determine positions of multiple objects concurrently disposed within capacitive sensing region 355. Of note, in this example, locations 305 and 310 correspond to separate capacitive sensor electrodes disposed substantially in parallel to axes 200, 205, and 210.

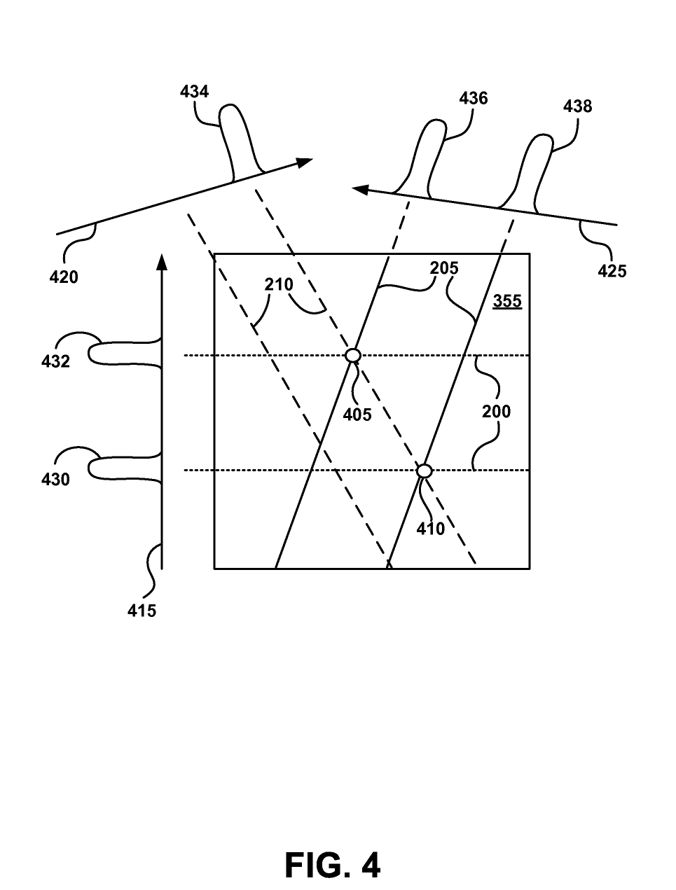

FIG. 4 is a diagram displaying objects concurrently disposed within capacitive sensing region 355 at locations 405 and 410 and corresponding graphs 415, 420, and 425. As will be described in detail below, graphs 415, 420, and 425 provide a graphical representation of indicia received from capacitive sensor electrodes disposed substantially in parallel to axes 200, 205, and 210.

Consider the example wherein two objects are concurrently disposed within capacitive sensing region 355. For purposes of the following example, assume once again that the two objects are comprised of a thumb and a pointer finger of a user. In such an example, location 405 represents the location at which the pointer finger interacts with capacitive sensing region 355. Similarly, location 410 represents the location at which the thumb interacts with capacitive sensing region 355. As shown on FIG. 4, location 405 corresponds to the intersection of capacitive sensor electrodes that are disposed substantially in parallel to axes 200, 205, and 210. Additionally, location 410 corresponds to the intersection of other capacitive sensor electrodes that are disposed substantially in parallel to axes 200, 205, and 210.

When the pointer finger is at location 405, indicia are generated by capacitive sensor electrodes disposed substantially in parallel to axes 200, 205, and 210, and are represented by peaks 432, 436, and 434 on graphs 415, 425, and 420 respectively. Similarly, when the thumb is at location 410, indicia are generated by capacitive sensor electrodes disposed substantially in parallel to axes 200, 205, and 210, and are represented by the peaks 430, 438, and 434 on graphs 415, 425, and 420 respectively.

However, in this example, there is only one peak 434 on graph 420 corresponding to locations 405 and 410 because indicia indicate that locations 405 and 410 reside on a single capacitive sensor electrode disposed substantially in parallel to axis 210. Based upon indicia received from this single capacitive sensor electrode, the locations of the thumb and the pointer finger are not clearly defined. The more indicia received from different capacitive sensor electrodes on different axes, the more clearly defined are locations 405 and 410. In this case, since locations 405 and 410 are located on the same capacitive sensor electrode disposed substantially in parallel to axis 210, the amount of indicia received will be reduced, thereby also making locations 405 and 410 less defined.

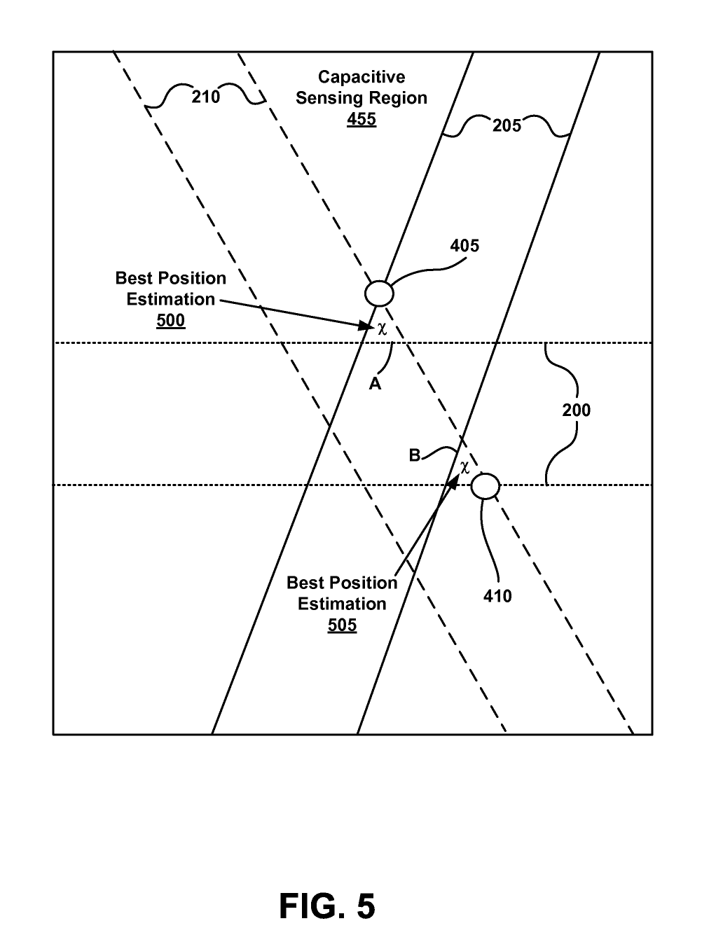

FIG. 5 is a diagram displaying an example best position estimation 500 and 505 for objects concurrently disposed within capacitive sensing region 355. In keeping with the example using a thumb and a pointer finger, once it is determined that an ambiguity is present with regards to the location of the thumb and the pointer finger, embodiments in accordance with the present technology determine the thumb's and the pointer finger's best position estimation 500 and 505, respectively.

Ideally, all projection lines associated with axes 200, 205, and 210 should intersect at a single point. However, due to the presence of noise and interpolation errors, there may be three intersection points for the first, second, and third plurality of capacitive sensor electrodes oriented along first, second, and third axes, 200, 205, and 210 respectively. In other words, as shown in FIG. 5, there is an intersection area represented by triangles A and B.

When input is received such that the thumb and the pointer finger are concurrently disposed within capacitive sensing region 355 on the same set of capacitive sensor electrodes disposed substantially in parallel to third axis 210 at locations 405 and 410, embodiments of the present technology are able to determine the mathematically proven best positioning of the thumb and the pointer finger by locating the center of triangles A and B.

It should be noted that axis 210, having only one peak 434, may be used for discrimination. The remaining two axes, axis 200 having two peaks 430 and 432, and axis 205 having two peaks 436 and 438, are utilized to determine the centers of triangles A and B respectively by computing coordinates.

In this case, the locations of the thumb and pointer finger along all three axes 200, 205, and 210 are first computed. Next, the coordinates, such as, for example, Cartesian coordinates, for the triangle centers 500 and 505 of triangles A and B, respectively, are computed. Triangle centers 500 and 505 are the best estimation for the positions corresponding to indicia received.

It should be noted that while thumb and pointer finger may be at locations 410 and 405, respectively, in other embodiments, thumb and pointer finger may be at any locations in the proximity of best estimations 505 and 500, respectively.

Thus, embodiments of the present technology enable the determination of the most accurate location 500 and 505 of multiple objects concurrently disposed within capacitive sensing region 355. The position of these objects may be determined under ideal conditions wherein all projection lines associated with multiple axes intersect at a single point. Additionally, the position of these objects may be determined even if the presence of noise and interpolation errors create distortions among the projection lines such that several intersection points exist. Embodiments provide for multiple objects (n) interacting with capacitive sensing region 355 to be sensed using multiple capacitive sensor electrodes disposed substantially in parallel to more than two axes (n+1). The resulting indicia is then used to determine an object's best estimated position for what may otherwise be an ambiguously positioned object.

In one embodiment, positions of multiple objects concurrently disposed within capacitive sensing region 355 are reported to an electronic system, such as controller 105.

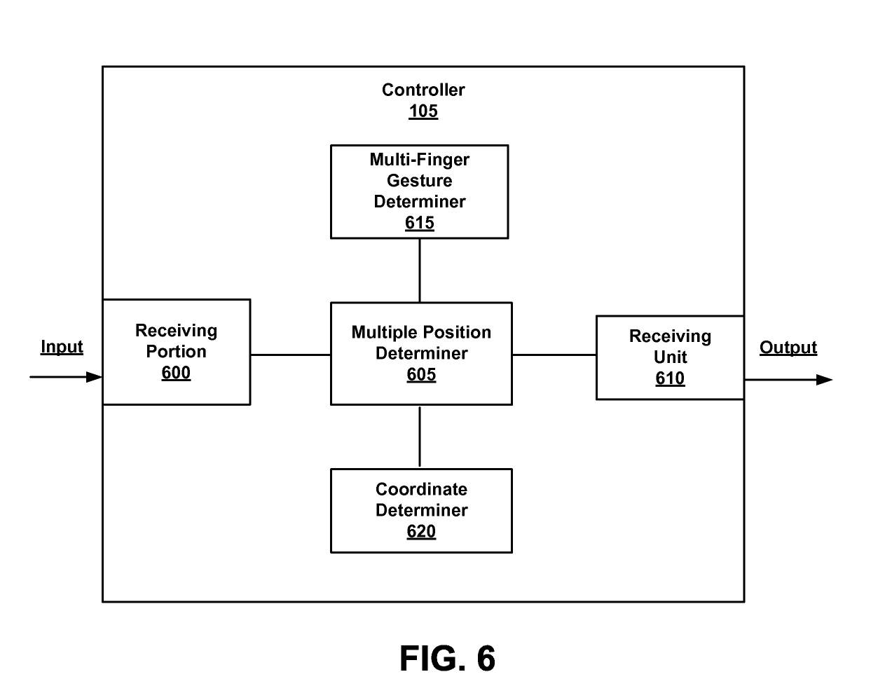

With reference to FIG. 6, a block diagram of an example controller 105 configured to determine the position of multiple objects concurrently disposed within capacitive sensing region 455 in accordance with an embodiment of the present technology is shown. Controller 105 includes receiving portion 600 and multiple position determiner 605. Multiple position determiner 605 is coupled with reporting unit 610, multi-finger gesture determiner 615, and coordinate determiner 620.

Referring to FIG. 6, in one embodiment receiving portion 600 is configured to receive indicia from at least three sets of capacitive sensing electrodes.

Referring still to FIG. 6, in one embodiment multiple position determiner 605 is coupled to receiving portion 600 and is configured to utilize indicia from the at least three sets of capacitive sensing electrodes to determine the position of the multiple objects concurrently disposed within the capacitive sensing region 355.

Referring to FIG. 6, in one embodiment reporting unit 610 is coupled to multiple position determiner 605. Reporting unit 610 is configured to output position information corresponding to the positions of multiple objects concurrently disposed within capacitive sensing region 355.

Referring still to FIG. 6, in one embodiment multi-finger gesture determiner 615 is coupled to multiple position determiner 605. Multi-finger gesture determiner 615 is configured to determine a multi-finger gesture. For example, multi-finger gesture determiner 615 is configured to determine a multi-finger gesture such as a thumb and pointer finger interacting within capacitive sensing region 355.

Referring to FIG. 6, in one embodiment, a coordinate determiner 620 is coupled to multiple position determiner 605. Coordinate determiner 620 is configured to determine, in at least a two dimensional coordinate system, the positions of multiple objects concurrently disposed within the capacitive sensing region 355.

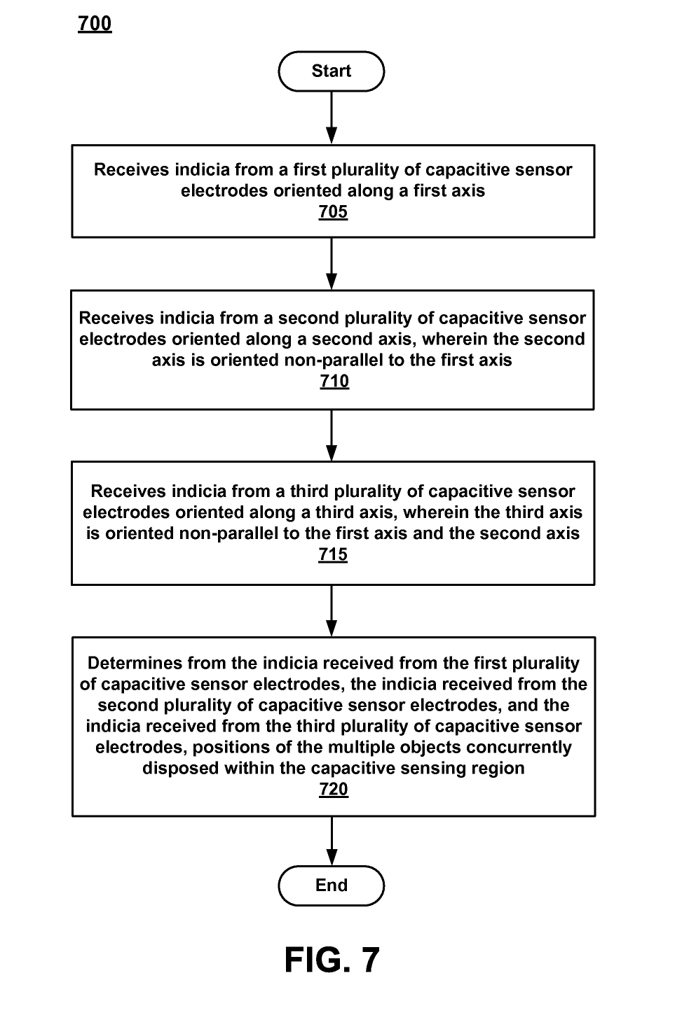

Referring now to 700 of FIG. 7, a flowchart of an example method for determining the position of multiple objects concurrently disposed within capacitive sensing region 355 in accordance with embodiments of the present technology is shown.

Referring to 705 of FIG. 7 and as described above, in one embodiment indicia from a first plurality of capacitive sensor electrodes disposed substantially in parallel to first axis 200 is received. Referring to 710 and 715 of FIG. 7, in one embodiment indicia from a second and third plurality of capacitive sensor electrodes disposed substantially in parallel to second 205 and third axis 210, respectively, is received. Second axis 205 is oriented non-parallel to first axis 200, and third axis 215 is oriented non-parallel to second axis 210.

Referring to 720 of FIG. 7 and as described above, positions of multiple objects concurrently disposed within capacitive sensing region 335 is determined from indicia received from first, second, and third plurality of capacitive sensor electrodes.

Thus, embodiments of the present technology provide a capacitive sensing apparatus for enabling the determination of positions of multiple objects concurrently disposed within capacitive sensing region 355. Controller 105 is provided which is configured to determine the position of multiple objects concurrently disposed within capacitive sensing region 355. Embodiments of the present technology utilize multiple axes (n+1) comprising a plurality of capacitive sensor electrodes projected onto a common plane and physically interdigitated to determine the positioning of n objects. In this manner, ambiguous and unambiguous sensed positions may be resolved to provide the best position estimation for each object.

The foregoing descriptions of specific embodiments have been presented for purposes of illustration and description. They are not intended to be exhaustive or to limit the presented technology to the precise forms disclosed, and many modifications and variations are possible in light of the above teaching. The embodiments were chosen and described in order to best explain the principles of the presented technology and its practical application, to thereby enable others skilled in the art to best utilize the presented technology and various embodiments with various modifications as are suited to the particular use contemplated. It is intended that the scope of the present technology be defined by the claims appended hereto and their equivalents.

What is claimed is:

1. A capacitive sensing apparatus configured to enable the determination of positions of multiple objects concurrently disposed within a capacitive sensing region, said capacitive sensor apparatus comprising:
a capacitive sensor array comprising:
a first plurality of capacitive sensor electrodes oriented along a first axis;
a second plurality of capacitive sensor electrodes oriented along a second axis; and
a third plurality of capacitive sensor electrodes oriented along a third axis, wherein said first axis, said second axis, and said third axis are oriented sufficiently non-parallel with respect to each other such that indicia received from said first plurality of capacitive sensor electrodes, said second plurality of capacitive sensor electrodes, and said third plurality of capacitive sensor electrodes can be used to enable said determination of said positions of said multiple objects concurrently disposed within said capacitive sensing region.

2. The capacitive sensing apparatus of claim 1 wherein a first sensor element comprising said first plurality of capacitive sensor electrodes is physically arranged with respect to a second sensor element comprising said second plurality of capacitive sensor electrodes such that, in a projection of said first sensor element and said second sensor element onto a common plane, said first sensor element and said second sensor element are physically interdigitated in a space filling pattern.

3. The capacitive sensing apparatus of claim 1 wherein said first axis, said second axis, and said third axis are arranged with substantially the same angle of separation there between.

4. The capacitive sensing apparatus of claim 1 wherein sensor elements comprising said first plurality of capacitive sensor electrodes are substantially diamond-shaped.

5. The capacitive sensing apparatus of claim 1 wherein sensor elements comprising said first plurality of capacitive sensor electrodes and sensor elements comprising said second plurality of capacitive sensor electrodes are located on separate layers.

6. The capacitive sensing apparatus of claim 1 wherein sensor elements comprising said first plurality of capacitive sensor electrodes and sensor elements comprising said second plurality of capacitive sensor electrodes are located on a common layer.

7. The capacitive sensing apparatus of claim 1 further comprising:
a controller coupled to said first plurality of capacitive sensor electrodes, said second plurality of capacitive sensor electrodes, and said third plurality of capacitive sensor electrodes, wherein said controller is configured to determine said positions of said multiple objects concurrently disposed within said capacitive sensing region.

8. A capacitive sensing device comprising:
a capacitive sensor array configured to enable the determination of positions of n objects concurrently disposed within a capacitive sensing region wherein n is at least 2, said capacitive sensor array comprising:
n+1 sets of capacitive sensor electrodes, each of said n+1 sets of capacitive sensor electrodes oriented along a respective axis of n+1 axes; said n+1 axes oriented sufficiently non-parallel with respect to each other such that indicia received from said n+1 sets of capacitive sensor electrodes can be used to enable said determination of said positions of said n objects concurrently disposed within said capacitive sensing region; and
a controller coupled to receive said indicia from said n+1 sets of capacitive sensor electrodes, said controller configured to utilize said indicia to determine said positions of said n objects concurrently disposed within said capacitive sensing region.

9. The capacitive sensing device of claim 8 wherein at least two sensor elements comprising different ones of said n+1 sets of capacitive sensor electrodes are physically arranged with respect to each other such that, in a projection of said at least two sensor elements onto a common plane, said at least two sensor elements are physically interdigitated in a space filling pattern.

10. The capacitive sensing device of claim 8 wherein said n+1 axes are arranged with substantially the same angle of separation there between.

11. The capacitive sensing device of claim 8 wherein said n+1 sets of capacitive sensor electrodes are comprised of substantially diamond-shaped sensor elements.

12. The capacitive sensing device of claim 8 wherein at least two sensor elements comprising different ones of said n+1 sets of capacitive sensor electrodes are located on separate layers.

13. The capacitive sensing device of claim 8 wherein at least two sensor elements comprising different ones of said n+1 sets of capacitive sensor electrodes are located on a common layer.

14. A method for determining the position of multiple objects concurrently disposed within a capacitive sensing region, said method comprising:
receiving indicia from a first plurality of capacitive sensor electrodes oriented along a first axis;
receiving indicia from a second plurality of capacitive sensor electrodes oriented along a second axis, wherein said second axis is oriented non-parallel to said first axis;
receiving indicia from a third plurality of capacitive sensor electrodes oriented along a third axis, wherein said third axis is oriented non-parallel to said first axis and said second axis; and
determining from said indicia received from said first plurality of capacitive sensor electrodes, said indicia received from said second plurality of capacitive sensor electrodes, and said indicia received from said third plurality of capacitive sensor electrodes, positions of said multiple objects concurrently disposed within said capacitive sensing region.

15. The method for determining the position of multiple objects concurrently disposed within a capacitive sensing region as recited in claim 14 wherein said receiving indicia from a first plurality of capacitive sensor electrodes, receiving indicia from a second plurality of capacitive sensor electrodes, and receiving indicia from a third plurality of capacitive sensor electrodes further comprises receiving indicia from a first plurality of capacitive sensor electrodes, receiving indicia from a second plurality of capacitive sensor electrodes, and receiving indicia from a third plurality of capacitive sensor electrodes which are oriented along axes having substantially the same angle of separation there between.

16. The method for determining the position of multiple objects concurrently disposed within a capacitive sensing region as recited in claim 14 further comprising:
utilizing said indicia received from said first plurality of capacitive sensor electrodes, said indicia received from said second plurality of capacitive sensor electrodes, and said indicia received from said third plurality of capacitive sensor electrodes, to unambiguously determine said positions of said multiple objects concurrently disposed within said capacitive sensing region.

17. The method for determining the position of multiple objects concurrently disposed within a capacitive sensing region as recited in claim 14 further comprising:
reporting, to an electronic system, said positions of said multiple objects concurrently disposed within said capacitive sensing region.

18. The method for determining the position of multiple objects concurrently disposed within a capacitive sensing region as recited in claim 14 further comprising:
utilizing said indicia received from said first plurality of capacitive sensor electrodes, said indicia received from said second plurality of capacitive sensor electrodes, and said indicia received from said third plurality of capacitive sensor electrodes to determine a multi-finger gesture.

19. The method for determining the position of multiple objects concurrently disposed within a capacitive sensing region as recited in claim 14 further comprising:
determining, in at least two coordinates, said positions of said multiple objects concurrently disposed within said capacitive sensing region.

20. A controller configured to determine the position of multiple objects concurrently disposed within a capacitive sensing region, said controller comprising:
a receiving portion, said receiving portion configured to receive indicia from at least three sets of capacitive sensing electrodes; and
a multiple position determiner coupled to said receiving portion, said multiple position determiner configured to utilize said indicia from said least three sets of capacitive sensing electrodes to determine said position of said multiple objects concurrently disposed within said capacitive sensing region.

21. The controller of claim 20 further comprising:
a reporting unit coupled to said multiple position determiner, said reporting unit configured to output position information corresponding to said positions of said multiple objects concurrently disposed within said capacitive sensing region.

22. The controller of claim 20 further comprising:
a multi-finger gesture determiner coupled to said multiple position determiner, said multi-finger gesture determiner configured to determine a multi-finger gesture.

23. The controller of claim 20 further comprising:
a coordinate determiner coupled to said multiple position determiner, said coordinate determiner configured to determine, in at least a two dimensional coordinate system, said positions of said multiple objects concurrently disposed within said capacitive sensing region.
